(19) United States
(12) Patent Application Publication
(10) Pub. No.: US 2011/0163442 A1
(43) Pub. Date: Jul. 7, 2011

(54) METHOD OF MANUFACTURING A PLURALITY OF ICS AND TRANSPONDERS

(75) Inventor: Christian Scherabon, Graz (AT)

(73) Assignee: NXP B.V., Eindhoven (NL)

(21) Appl. No.: 13/063,978

(22) PCT Filed: Sep. 8, 2009
(86) PCT No.: PCT/IB2009/053902

§ 371 Date: Mar. 15, 2011

(30) Foreign Application Priority Data
Sep. 15, 2008 (EP) 08105341.5

(51) Int. Cl. H01L 23/485; H01L 21/60

(52) U.S. Cl. 257/737; 438/613; 257/E21.508; 257/E23.021

(57) ABSTRACT

A method of manufacturing a plurality of ICs for different transponder types adapted for different operating range is provided, wherein the method comprises manufacturing a first IC having a first capacitance corresponding to a first operating range of the first transponder and manufacturing a second IC having a second capacitance corresponding to a second operating range of the second transponder, wherein a common layout is used for manufacturing the first IC and the second IC.

### FIELD OF THE INVENTION

The invention relates to a method of manufacturing a plurality of ICs, in particular of ICs for a transponder.

Beyond this, the invention relates a method of manufacturing a plurality of transponders.

Furthermore, the invention relates to a set of ICs.

In addition, the invention relates to a set of transponders.

### BACKGROUND OF THE INVENTION

RFID tags or transponders are widely used nowadays for tagging items or bunches of items. In general there are two main application fields for UHF RFID tags which are distinct to each other mainly due to the intended operating distance, namely the so called long range or far field applications having an operating distance of several meters. These long range applications are used for bunch or palette tagging, for example. The other main application is the so called short range or near field applications corresponding to an operating distance of less than one meter. These short range applications are mainly used for item tagging.

Due to physical reasons both applications use different antenna types. For the long range applications dipole antennas are used which have a high efficiency to sense electromagnetic waves, in particular the electric part. Contrary to that loop antennas are used for the short range applications which are particularly sensitive to magnetic fields.

The adaptation of the transponder for the different applications may thus lead to increased design and manufacturing costs.

### OBJECT AND SUMMARY OF THE INVENTION

It may be a need to provide a method of manufacturing a plurality of ICs for transponders, a method of manufacturing a plurality of transponders, a plurality of ICs for transponders, and a plurality of transponders.

In order to meet the need defined above, a method of manufacturing a plurality of ICs for transponders, a method of manufacturing a plurality of transponders, a plurality of ICs for transponders, and a plurality of transponders according to the independent claims are provided. Further embodiments are described in the dependent claims.

According to an exemplary aspect of the invention a method of manufacturing a plurality of ICs for different transponder types adapted for different operating range is provided, wherein the method comprises manufacturing a first IC having a first capacitance corresponding to a first operating range of the first transponder and manufacturing a second IC having a second capacitance corresponding to a second operating range of the second transponder, wherein a common layout is used for manufacturing the first IC and the second IC.

In particular, the first operating range or distance may correspond to a near field operating range while the second operating range or distance may correspond to a far field operating range. The transponder may be an RFID tag, e.g. an UHF RFID tag. In particular, the common layout may be a common wafer scale layout.

According to an exemplary aspect of the invention a method of manufacturing a plurality of transponders types is provided, wherein the method comprises a method according to an exemplary aspect of the invention, forming a first contact bump having a first height on the first IC, forming a second contact bump having a second height on the second IC, wherein a height of the first bump and the second bump is different, connecting a first antenna structure to the first contact bump, and connecting a second antenna structure to the second contact bump. In particular, a set of first contact bumps and/or a set of second contact bumps may be formed on the first IC and the second IC, respectively. For example, two first contact bumps may be formed on the first IC and two second contact bumps may be formed on the second IC.

According to an exemplary aspect of the invention a set of ICs for transponders adapted for different operating ranges is provided, wherein the set comprises a first IC having a first capacitance corresponding to a first operating range, and a second IC having a second capacitance corresponding to a second operating range, wherein the first IC and the second IC have a common layout.

In particular, the first operating range or distance may correspond to a near field operating distance while the second operating range or distance may correspond to a far field operating distance.

According to an exemplary aspect of the invention, a set of transponders adapted for different operating ranges is provided, wherein a first one of the set of transponders comprises a first one of a set of ICs according to an exemplary aspect of the invention, which is adapted for a first operating range, and wherein a second one of the set of transponders comprises a second one of the set of ICs according to an exemplary aspect of the invention and each of the set of transponders comprises at least one IC according to an exemplary aspect of the invention, which is adapted for a second operating range.

According to an exemplary aspect of the invention, a method of adapting an IC having a predetermined layout for a use in a transponder of a specified operating range, wherein the method comprises manufacturing the IC and forming a contact bump on the IC wherein the contact bump is connectable to an antenna structure to form the transponder of the specified operating range. In particular, a set of contact bumps may be formed on the IC.

According to an exemplary aspect of the invention, a method of adapting an IC for the use in a transponder having a specific operating distance is provided, wherein the method comprises, providing an IC and forming a contact bump on the IC having a height which is adapted in such a way that the IC provides a specific capacitance value when connected to an antenna structure.

According to an exemplary aspect of the invention, a method of adapting a transponder having a predetermined IC layout to a specific operating distance is provided, wherein the method comprises manufacturing an IC and manufacturing a contact bump connectable to an antenna structure, wherein a height of the contact bump is determined based on a desired capacity of the IC. In particular, for a short range application the height may be chosen to be greater than for a long range application.

The term “common layout” may particularly denote the fact that the same masks may be used to manufacture the different ICs, while the heights of the different ICs may be distinct from each other, e.g. one IC of the plurality of ICs may comprise a layer which has a height which is smaller or greater than the corresponding layer of another IC of the plurality of ICs. Thus, a top view on the IC may be similar or identical while a cross sectional view may be different. However, a common layout may also include small deviations between different ICs, e.g. small deviations caused by manufacturing tolerances or by small design differences which are introduced for different purposes but which are not intended to match the capacitance of the respective IC to a specific value. That is, in general the matching of the capacity or capacitance to a specific operating range is not performed by altering the layout of the ICs.

The term “near field” may particularly denote an operating distance of less than one meter.

The term “far field” may particularly denote an operating distance of more than one meter up to several meters.

The transponders may be adapted for a contactless transmission, wherein the term “contactless transmission” may particularly denote a transmission of a signal, or analog or digital data from a sending unit to a receiving unit, wherein the sending unit and the receiving unit are not directly connected by a connection line, e.g. either an electrically conductive line or a connection line adapted to transmit light. Thus a contactless transmission may be performed by an electromagnetic wave of any suitable frequency, e.g. a radio wave, a microwave, or a wave of infrared light.

By providing a set of ICs comprising at least two types of ICs which are adapted for different operating ranges by having different values of capacitance, it may be possible to use the same layout for long range applications and short range applications. The use of a common layout may decrease the design costs and the manufacturing costs and the respective design time. It may also be possible to use a method according to an exemplary aspect of the invention together with already known design layouts of ICs in order to increase the flexibility of the applications. For example, when manufacturing ICs an additional step or an adaptation of a specific step may be performed increasing or decreasing the capacitance of the IC by choosing a specific manufacturing parameter according to the desired capacitance value. In particular, the adaptation may be performed by using the so called parasitic capacitance of the ICs to set the desired capacitance value of the IC. This parasitic capacitance may, for example, depend on the thickness of the IC or the distance between the IC and an antenna structure of a respective transponder. Furthermore, the capacitance may be altered by using different materials arranged between the IC and the antenna structure and/or by altering the area covered by the antenna structure, e.g. by conductor paths of the antenna structure.

Thus, it may be possible to provide one IC layout which can be used for item tagging, which is commonly thought to be an HF domain, while using UHF so that it may be possible to use a common infrastructure for long range and short range applications. By providing a common IC layout having different capacitance values it may be possible to use the same chip layout for both ranges although the respective applications may demand different chip capacitances. For example, for long range applications the chip capacitance should be great so that smaller loops may be usable, which need less space on the transponder, RFID tag or label, which may reduce costs, and which may provide a more constant current distribution when applied to different items so that the transponder may be less prone to detuning. Furthermore, a great chip capacitance may reduce bad effects of differences of the capacity, e.g. of parasitic or original capacitance, due to tolerances. Contrary to that, short range applications may need small capacitances so that greater loops may be used in order to increase a coupling.

It may be seen as a gist of an exemplary aspect of the invention that ICs for different operating ranges may be manufactured by using the same layout but having different capacitance values, wherein the capacitance values may include a parasitic capacitance portion which may be adjusted according to the needed capacitance values of the IC. Such an adjustment may be performed by increasing the thickness of the IC or the distance between the IC and an antenna structure, e.g. by providing a contact area ensuring a specific distance between the IC and the antenna structure when the antenna structure is connected to the IC.

Next, further exemplary embodiments of the method of manufacturing a plurality of ICs for transponders are described. However, these embodiments also apply to the method of manufacturing a plurality of transponders, a plurality of ICs for transponders, and a plurality of transponders.

According to another exemplary embodiment the method further comprises forming a first contact bump having a first height on the first IC, forming a second contact bump having a second height on the second IC, wherein a height of the first bump and the second bump is different.

In particular, the contact bumps may be formed by using known deposition process steps, e.g. by a plating process. This step may be the last process step of the IC. For example, the first and/or second bump may comprise or may be formed of gold. In particular, the first contact bump may have a greater height than the second contact bump leading to a first IC which may be adapted for a short range application while the second IC may be adapted or may be more suitable for a long range application than the first IC. Of course more than one first contact bumps and/or more than one second contact bumps may be formed.

According to another exemplary embodiment of the method, the first and second height may be determined by setting a time period for the forming step of the first and/or second contact bump.

That is, it may be possible to achieve different heights of the different bumps by adapting a deposition step used for forming or manufacturing the bumps. For example, a longer deposition period may lead to a greater height of the bump while choosing a shorter deposition period a smaller height of the bump may be achievable.

According to another exemplary embodiment of the method, the first and second heights may be adjusted by reducing a thickness of the first contact bump and/or the second contact bump.

In particular, the heights may be adjusted by reducing an original height or thickness of the first and/or second bump by grinding, polishing or other suitable removing processes. Furthermore, the height of the first and/or second contact bump may be adjusted by reducing the height of an original layer which is then patterned to form the first and/or second contact bump.

According to another exemplary embodiment, the method further comprises connecting a first antenna structure to the first contact bump and connecting a second antenna structure to the second contact bump.

In particular, the first and the second antenna structure may have the same layout. For example, the antenna structure may comprise a loop element and/or a dipole element.

Summarizing, an exemplary aspect of the invention may be seen in providing a method of manufacturing a set of ICs for transponders wherein the transponders are adapted for at least two different operating ranges, e.g. short and long range applications. According to common methods two different integrated chips are used to cover both applications wherein the different ICs have different impedances, e.g. a high input capacitance of about 1 to 2 pico farad (pF) and a low input capacitance of about 400 femto farad (fF) to 1 pF in order to be able to manufacture great loop antennas of about 2 cm. According to the exemplary aspect these different capacitances are achieved by using a common design for both applications used to provide two different types of ICs which are different in principle only in the height of a bump which can be used to connect the ICs to an antenna structure of the transponder. A basic principle of the invention may be in exploiting the effect that by attaching an antenna structure to the IC by using the so called direct chip attach method parasitic capacitances are introduced additional to the chip original chip capacitance. These parasitic capacitances may be used in order to adapt the overall capacitance value of the IC to the respective operating range. The value of the parasitic capacitance may depend mainly on the bump height, i.e. the distance between the IC and the connected antenna. Thus, by using the parasitic capacitance it may be possible to provide an additional capacitance in the range of about 200 fF, corresponding to a bump height of about 30 micrometer (μm) or more, to about 1 pF, corresponding to a bump height of about several μm. Therefore, a variation by a factor of about 2 may be achievable by varying the bump height when the chip has an original capacitance of about 400 fF to 800 fF. In the same amount the size of the loop antenna may be varied. Thus, it may be possible to use the same design layout possibly saving design and manufacturing costs.

The aspects defined above and further aspects of the invention are apparent from the examples of embodiment to be described hereinafter and are explained with reference to these examples of embodiment. It should be noted that features or steps described above in the context of one exemplary embodiment or aspect may also be combined with another exemplary embodiment or aspect.

### BRIEF DESCRIPTION OF THE DRAWINGS

The invention will be described in more detail hereinafter with reference to examples of embodiment but to which the invention is not limited.

FIG. 1 schematically illustrates an antenna structure for a long range application.

FIG. 2 schematically illustrates an antenna structure for a short range application.

FIG. 3 schematically illustrates a cross sectional view of a transponder according to an exemplary embodiment of the invention.

### DESCRIPTION OF EMBODIMENTS

The illustration in the drawing is schematically. In different drawings, similar or identical elements are provided with similar or identical reference signs.

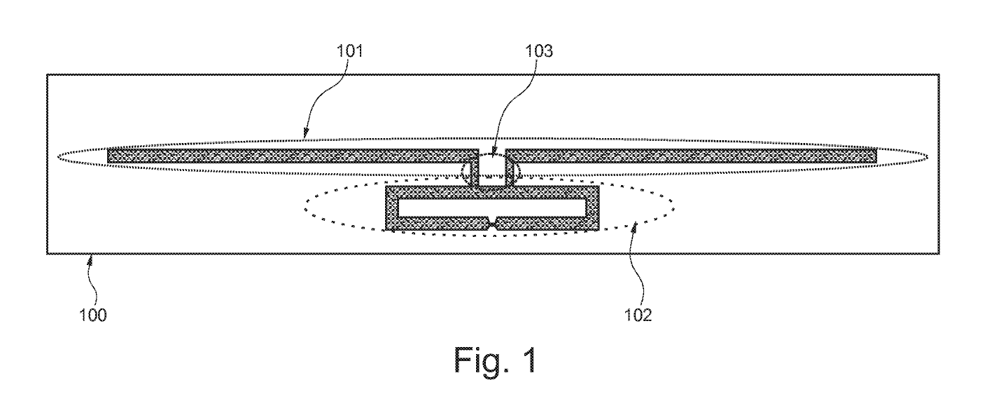

FIG. 1 schematically shows an antenna structure adapted for a long range application. In detail FIG. 1 shows a top view of a substrate 100 having arranged thereon a dipole element or dipole antenna 101 and a loop element 102 connected with each other by a conductor 103.

These two elements have different task for long and short range applications. For the long range application the loop forms an inductivity which, together with the RFID chip, forms a resonance circuit and thus determines the resonance frequency of the antenna. Together with the dipole element forming the antenna, the electromagnetic wave is sensed. It should be noted that the inductivity of the loop is approximately proportional to the circumference:

$${L}_{A} = {μ}_{0} a [ ln ( \frac{8 a}{b} ) - 2 ]$$

wherein a corresponds to the diameter of the loop and b corresponds to the diameter of the conductor the loop is build of.

As already mentioned due to two reasons the capacity of the chip of the RFID tag should be as great as possible because:

Having a great capacity of the chip may enable the use of small loops, which need less space and possibly enable an improved current distribution so that the transponder may be less prone to detuning on different items. Furthermore, the IC chip and/or the respective transponder may be less prone to negative effects of manufacturing tolerances.

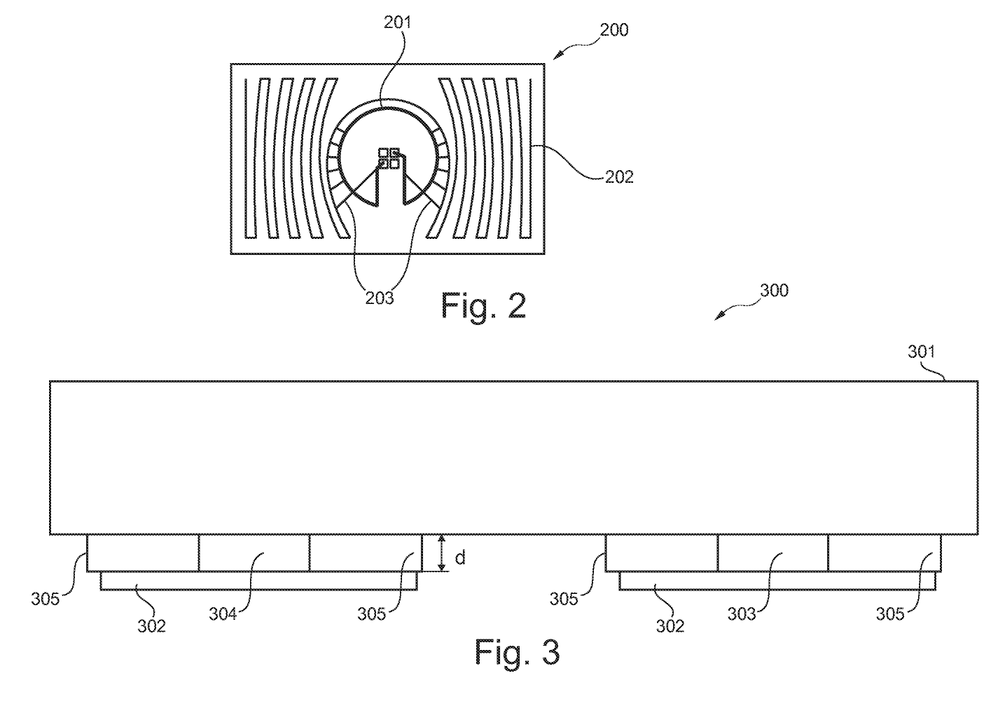

FIG. 2 schematically illustrates an antenna structure for a short range application. In detail FIG. 2 shows a top view of a substrate 200 having arranged thereon a dipole element or dipole antenna 202 and a loop element 201 connected with each other by a conductor 203. In short range application, resulting in smaller antennas, the two elements of the antenna structure have other functions. In particular, the loop element is used for coupling to the magnetic component of the electromagnetic field or wave while the dipole element, which is smaller in this case compared to the long range application, serves for improving the matching. However, the dipole element may also be used for mid range applications, e.g. 1 to 2 meter. In case of the short range application a small chip capacitance may be advantageous so that greater loops can be used possibly leading to an improved coupling. In that case a compromise between sensitivity and tolerances with respect to the assembly and the loop size may be necessary.

FIG. 3 schematically illustrates a cross sectional view of a transponder according to an exemplary embodiment of the invention. In particular, FIG. 3 shows a schematic cross sectional view of a transponder 300 comprising an IC chip 301 and an antenna structure 302 formed by copper and attached to the IC 301 by a so called direct chip attach connection. For the connection contact bumps 303 and 304 are formed on the IC chip 301. For example, the contact bumps may be formed by gold and may have a height or thickness labeled d in FIG. 3. Additionally, an adhesive 305 may be used to fix the antenna structure onto the IC chip. The contact bumps 303 and 304 are used as a distance piece or spacer ensuring that a predetermined distance between the IC chip and the antenna structure is kept. Further to the original capacitance of the IC chip the overlapping of the IC chip and the antenna structure generates a parasitic capacitance which can be approximated by a plate capacitor. Given a predetermined overlapping area the distance d and potentially the dielectric constant of the adhesive are the parameters determining the parasitic capacitance. The bump itself also provides an additional amount of capacitance:

$$C = \frac{ɛ \cdot A}{d}$$

wherein C corresponds to the parasitic capacitance, c corresponds to the dielectric constant, A corresponds to the overlapping area and d corresponds to the distance between the IC chip and the antenna structure.

Thus, by adjusting the height of the bump and therefore the distance d in a deposition process the overall capacitance of the IC chip and of the transducer may be adjustable while still using the same layout, e.g. while still using the same masks for processing. The thickness may be adjusted by choosing a corresponding time period for a deposition process of the contact bump. That is, in a last process step of the IC chip the IC chip may be adaptable for a specific desired application, e.g. for a long range application or a short range application. In some cases a specific mask may be used for ensuring the desired overall capacitance value for the IC chip.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. A method of manufacturing a plurality of ICs for different transponder types adapted for different operating range, the method comprising:
manufacturing a first IC for a first transponder with a first operating range;
manufacturing a second IC for a second transponder with a second operating range; and
wherein the same masks are used for manufacturing the first IC and the second IC while the heights of the ICs may be distinct from each other,
characterized in that the method further comprises:
forming a first contact bump having a first height on the first IC,
forming a second contact bump having a second height on the second IC,
wherein a height of the first bump and the second bump is different and wherein the heights of the first and second bumps are selected to provide a desired overall capacitance of the respective IC and associated transponder.

2. (canceled)

3. The method according to claim 1,
wherein the first and second heights are determined by setting a time period for the forming step of the first contact bump and/or second contact bump.

4. The method according to claim 1,
wherein the first and second heights are adjusted by reducing a thickness of the first contact bump and/or the second contact bump.

5. The method according to claim 1, further comprising:
connecting a first antenna structure to the first contact bump,
connecting a second antenna structure to the second contact bump.

6. (canceled)

7. (canceled)

8. (canceled)

9. A set of ICs for transponders adapted for different operating ranges, the set comprising:
a first IC for a first transponder with a first operating range;
a second IC for a second transponder with a second operating range. Wherein the same masks are used for manufacturing the first IC and the second IC while the heights of the ICs may be distinct from each other;
a first contact bump having a first height on the first IC; and
a second contact bump having a second height on the second IC,
wherein a height of the first bump and the second bump is different, and wherein the height of the first and second bumps are selected to provide a desired overall capacitance of the respective IC and associated transponder.

10. (canceled)
